(19) United States
(12) Patent Application Publication
(10) Pub. No.: US 2026/0255537 A1
(43) Pub. Date: Aug. 27, 2026

(54) DUO-PUMP LIQUID COOLING DEVICE

(71) Applicant: SHENZHEN APALTEK CO., LTD., Shenzhen (CN)

(72) Inventors: Qineng XIAO, Dongguan (CN); Dagao ZHENG, Shenzhen (CN); Dabiao LING, Shenzhen (CN)

(21) Appl. No.: 19/234,199

(22) Filed: Jun. 10, 2025

(30) Foreign Application Priority Data
Feb. 27, 2025 (CN) 2025102282602

(51) Int. Cl. H05K 7/20

(52) U.S. Cl. CPC H05K 7/20272

(57) ABSTRACT

A duo-pump liquid cooling device having a base seat, two pumps, a separating assembly, and a bottom seat is provided. The base seat includes a first and a second seat and has two channels. The first seat has an outlet port and a confluence cavity communicated to each other. The second seat has an inlet port and a concentrated cavity communicated to each other and two accommodated grooves. The pumps are corresponding to the accommodated grooves. The separating assembly covers the confluence cavity and has a through slot group. The first seat is arranged on the bottom seat to form a heat exchange chamber between thereof. The channels are communicated to the heat exchange chamber and the accommodated grooves. The heat exchange chamber is communicated to the confluence cavity through the through slot group. The duo-pump liquid cooling device is therefore increasing coolant flow and improving heat dissipation efficiency.

### BACKGROUND

### Technical Field

The present disclosure relates to the field of liquid cooling, particularly to a duo-pump liquid cooling device.

### Description Of Related Art

In a liquid cooling system, a coolant is sealed and filled in a closed loop to flow cyclically, and the coolant is used as a medium to carry a heat from a heat source to a heat dissipator for cooling and heat dissipation. Therefore, most liquid cooling systems use a pump to make the coolant to flow, and a heat dissipation efficiency of the entire liquid cooling system is better when a flow rate of the coolant is faster.

As electronic technology develops towards thinner and more powerful, the heat generated thereof has also increased significantly. However, the heat dissipator with single pump may only drive a limited flow rate of the coolant such that the heat dissipation efficiency thereof is insufficient. In addition, in order to cope with the thinner design, a capacity of the coolant may be reduced when the overall volume of the liquid cooling system is reduced. Therefore, after a period of use, the coolant would not be sufficient due to evaporation or leakage to affect the operation of the liquid cooling system.

In view of the above, the inventor seeks to overcome the aforementioned drawbacks associated with the current technology and aims to provide an effective solution through extensive researches along with utilization of academic principles and knowledge.

### SUMMARY

The primary objective of the present disclosure is to increase the flow rate of the coolant in the duo-pump liquid cooling device to improve heat dissipation efficiency and prevent the coolant from becoming insufficient due to evaporation or leakage after a period of use.

To accomplish the aforementioned objective, the present disclosure provides a duo-pump liquid cooling device having a base seat, a pair of pumps, a separating assembly, and a bottom seat. The base seat includes a first seat and a second seat and has a pair of channels. The second seat is arranged on the first seat. The first seat has an outlet port and a confluence cavity communicated to the outlet port. The second seat has an inlet port, a concentrated cavity, and a pair of accommodated grooves. The inlet port is communicated to the concentrated cavity. Each of the accommodated grooves is arranged in parallel and respectively communicated to the concentrated cavity. The concentrated cavity is completely located between the confluence cavity and the pair of accommodated grooves. Each of the channels is corresponding to each of the accommodated grooves and located on two sides of the concentrated cavity. Each of the pumps is corresponding to each of the accommodated grooves. The separating assembly covers the confluence cavity and has a through slot group. The first seat is arranged on the bottom seat to form a heat exchange chamber between the separating assembly and the bottom seat. Two ends of each of the channels are respectively communicated to the heat exchange chamber and the corresponding accommodated groove. The heat exchange chamber is communicated to the confluence cavity through the through slot group.

Another aspect of the present disclosure provides that the bottom seat has a plurality of fins arranged in parallel, a plurality of flow channels is formed between each two of the fins, two ends of each of the flow channels are communicated to each of the channels, each of the flow channels is communicated to the confluence cavity through the through slot group.

Another aspect of the present disclosure provides that each of the fins separates the heat exchange chamber to each of the flow channels, a pair of shunt areas, and a pair of inflow areas, two ends of each of the flow channels are respectively communicated to each of the inflow areas, two ends of each of the inflow areas are respectively communicated to each of shunt areas, each of the inflow areas and each of the fins are located between each two of the shunt areas, an end of each of the channels communicated to the heat exchange chamber is communicated to the corresponding shunt area.

Another aspect of the present disclosure provides that a location of each of the channels communicated to the corresponding shunt area is located at a center of the shunt area.

Another aspect of the present disclosure provides that the separating assembly includes a separating plate and a diversion plate, the separating plate is arranged between the first seat and the diversion plate.

Another aspect of the present disclosure provides that the separating assembly further includes an abutting sheet, the abutting sheet is arranged between the diversion plate and the bottom seat, the abutting sheet has a pair of limiting baffles, the diversion plate has a pair of positioning baffles, the diversion plate is limited between each two of the limiting baffles, the abutting sheet is limited between each two of the positioning baffles and located between each two of the limiting baffles.

Another aspect of the present disclosure provides that the second seat includes a main body and a cover plate, the main body has the inlet port, the concentrated cavity, and the accommodated grooves, the cover plate has a pair of mounting grooves, is arranged on the main body, and covers each of the accommodated grooves, each of the mounting grooves is configured to be corresponding to each of the accommodated grooves.

Another aspect of the present disclosure provides that each of the pumps includes a stator assembly and a rotor assembly, each of the rotor assemblies is arranged in each of the accommodated grooves, each of the stator assemblies is arranged in each of the mounting grooves.

Another aspect of the present disclosure provides that each of the channels includes a first channel section and a second channel section communicated to each other, each of the first channel sections is defined on the first seat and communicated to the heat exchange chamber and the corresponding second channel section, each of the second channel sections is defined on the second seat and communicated to the corresponding accommodated groove and the corresponding first channel section

Another aspect of the present disclosure provides that the inlet port and the outlet port are located on same side of the base seat.

In the duo-pump liquid cooling device of the present disclosure, the second seat forms the concentrated cavity, and the pumps are arranged in the accommodated grooves in parallel. Therefore, the coolant may converge in the concentrated cavity after entering from the inlet port, and then the coolant sequentially enters the accommodated grooves, the channels, and the heat exchange chamber by a suction force generated by the pumps when they are running. The duo-pump liquid cooling device of the present disclosure is therefore increasing the flow rate of the coolant therein to improve heat dissipation efficiency and preventing the coolant from becoming insufficient due to evaporation or leakage after a period of use.

### BRIEF DESCRIPTION OF THE DRAWINGS

FIG. 1 is an exploded view of the present disclosure;

FIG. 2 is another exploded view of the present disclosure;

FIG. 3 is an exploded view of the base seat of the present disclosure;

FIG. 4 is a perspective appearance view of the present disclosure;

FIG. 5 is a cross-sectional front view of the present disclosure;

FIG. 6 is a cross-sectional side view of the inlet port of the present disclosure;

FIG. 7 is a cross-sectional side view of the outlet port of the present disclosure;

FIG. 8 is a cross-sectional top view of the present disclosure;

FIG. 9 is a cross-sectional view along A-A of FIG. 5;

FIG. 10 is a cross-sectional view along B-B of FIG. 5; and

FIG. 11 is a cross-sectional view along C-C of FIG. 5.

### DETAILED DESCRIPTION

It is to be understood that the terms for indicating positions and the location relation, for example “front”, “rear”, “left”, “right”, “front end”, “rear end”, “distal end”, “longitudinal direction”, “lateral direction”, “vertical direction”, “top” and “bottom”, are based on the positions and the location relation disclosed in the drawings, and only used for disclosing the present disclosure and not used for indicating or implying the specified location of the device or the components or the specified structure and operation in certain location, thus the present disclosure is not intended to be limiting.

For example, the terms of “first”, “second”, “third”, “forth” and “fifth” are used for illustrating each unit, component, area, layer and/or part. The component, the unit, the area, the layer and/or the part are not limited by the terms. These terms are only used for separating the element, the assembly, the area, the layer, or the part. Unless being clearly indicated according to the whole specification, the terms for example “the first”, “the second”, “the third”, “the fourth” and “the fifth” are not used for implying the order or sequence.

As used herein and not otherwise defined, the terms "substantially" and "approximately" are used to describe and describe small changes. When used in connection with an event or situation, the terms may include the precise moment at which the event or situation occurs, as well as the event or situation occurring to a close approximation. For example, when combined with a numerical value, the terms may include a range of variation equal to or less than ±5% of the numerical value, such as equal to or less than ±4%, equal to or less than ±3%, equal to or less than ±2%, equal to or less than ±1%, equal to or less than ±0.5%, equal to or less than ±0.1%, or equal to or less than ±0.05%.

The technical contents of the present disclosure will become apparent with the detailed description of embodiments and the accompanied drawings as follows. However, it shall be noted that the accompanied drawings are for illustrative purposes only such that they shall not be used to restrict the scope of the present disclosure.

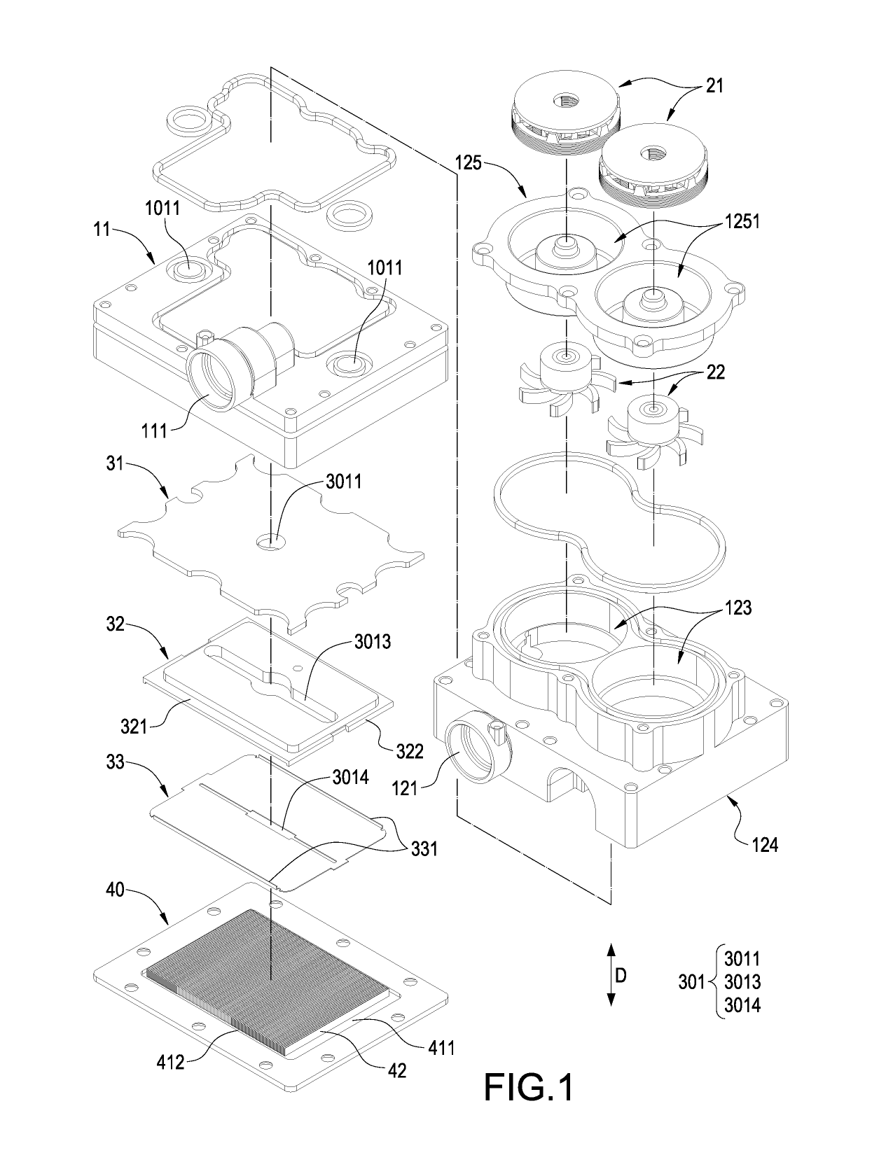

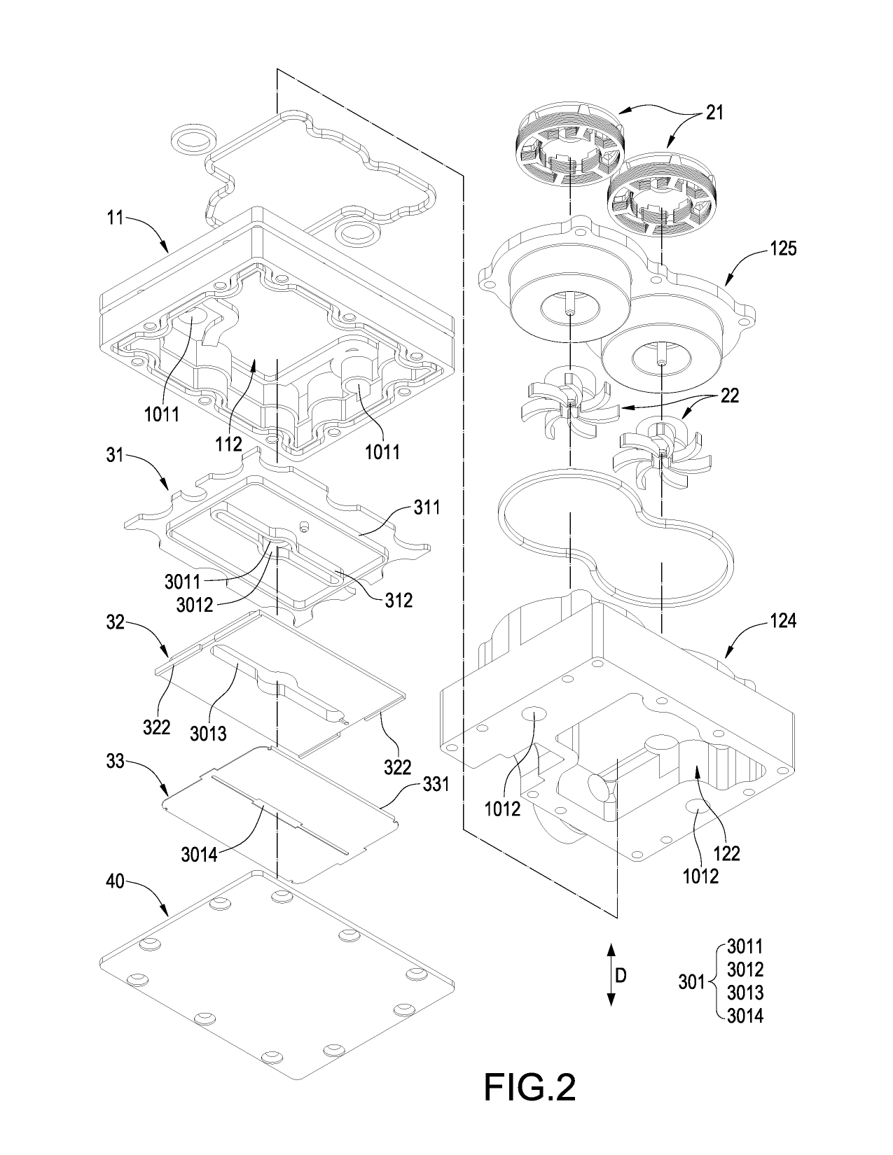

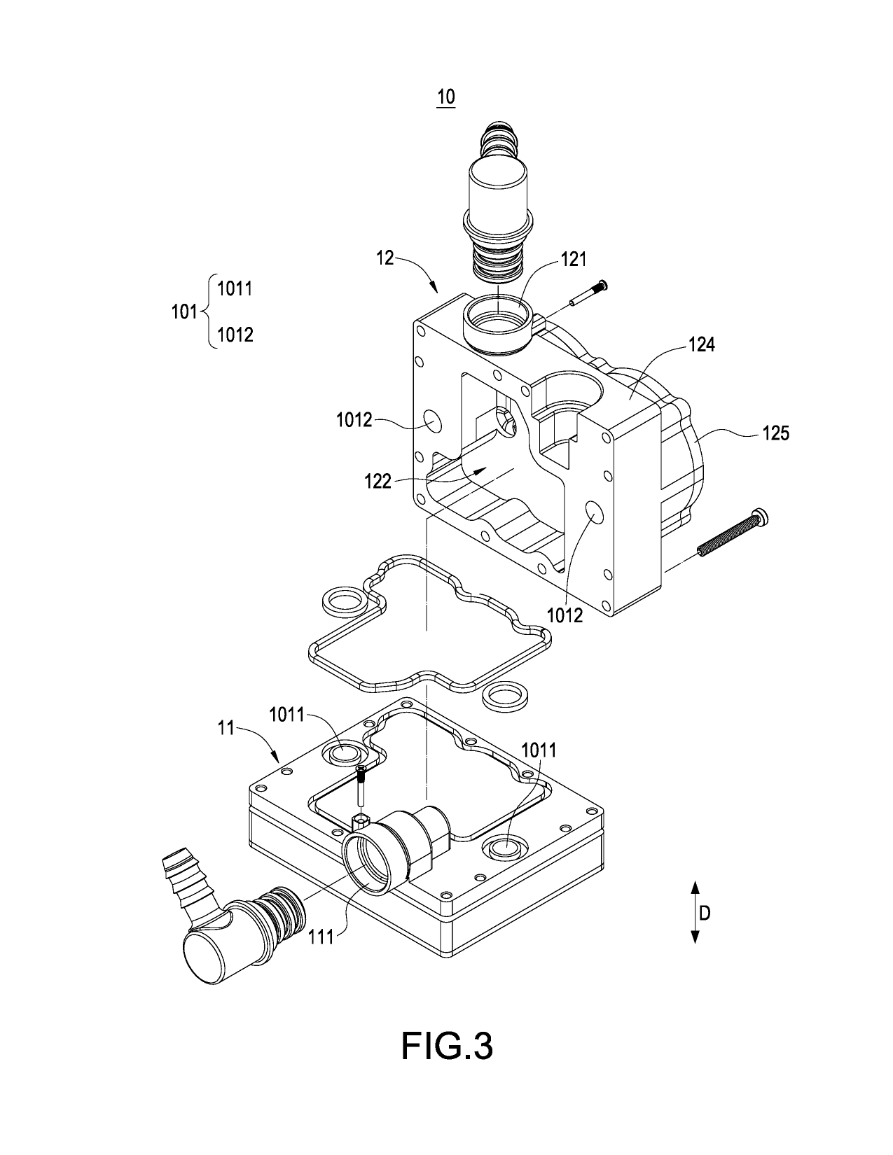

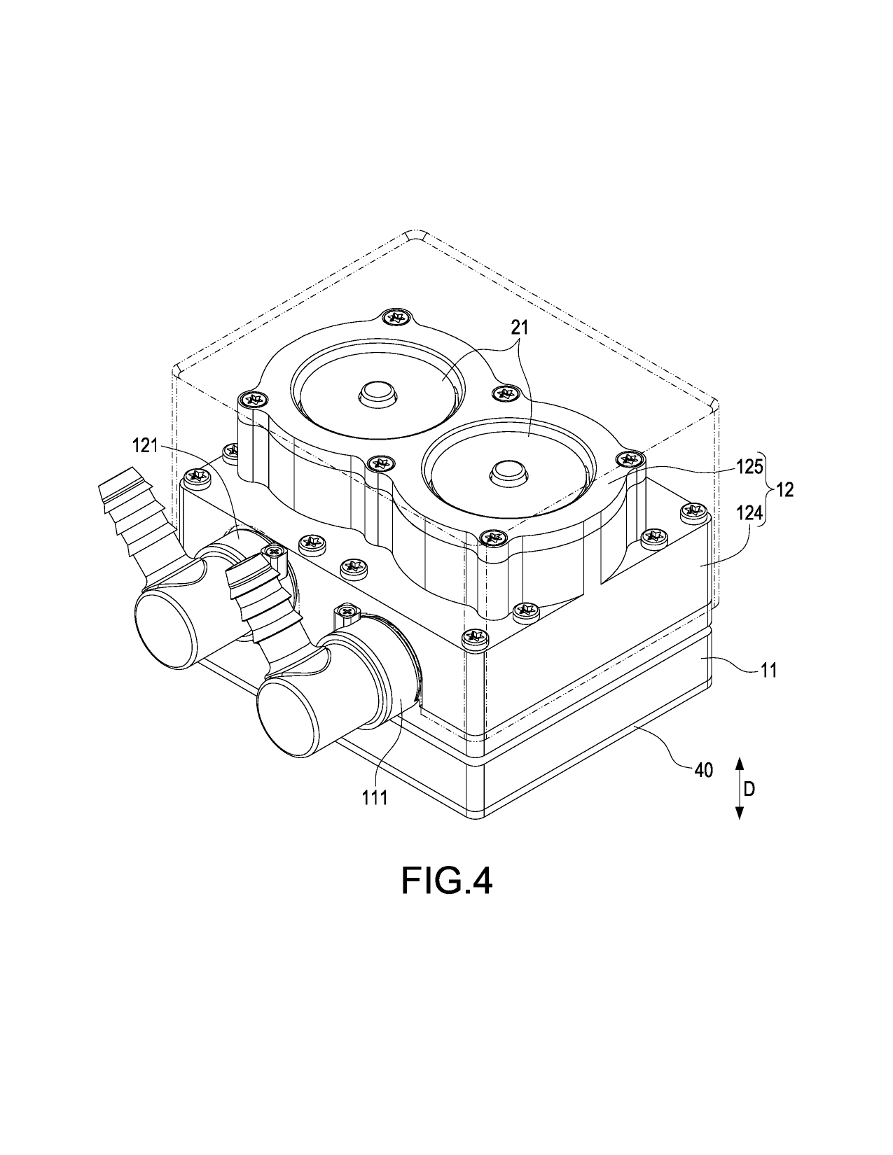

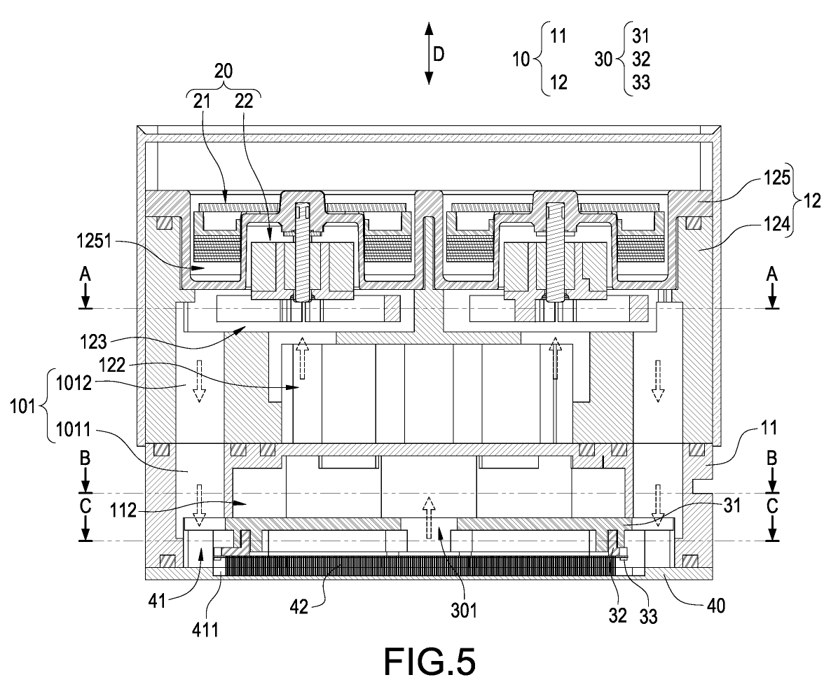

The present disclosure provides a duo-pump liquid cooling device for a coolant to flow through. Please refer to FIG. 1, FIG. 2, FIG. 3, FIG. 4, and FIG. 5, the duo-pump liquid cooling device of the present disclosure includes a base seat 10, a pair of pumps 20, a separating assembly 30, and a bottom seat 40.

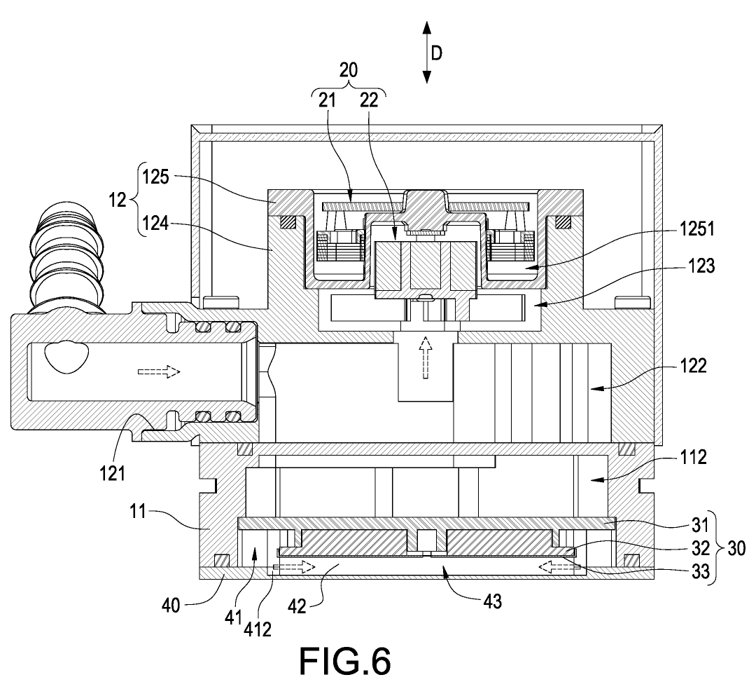

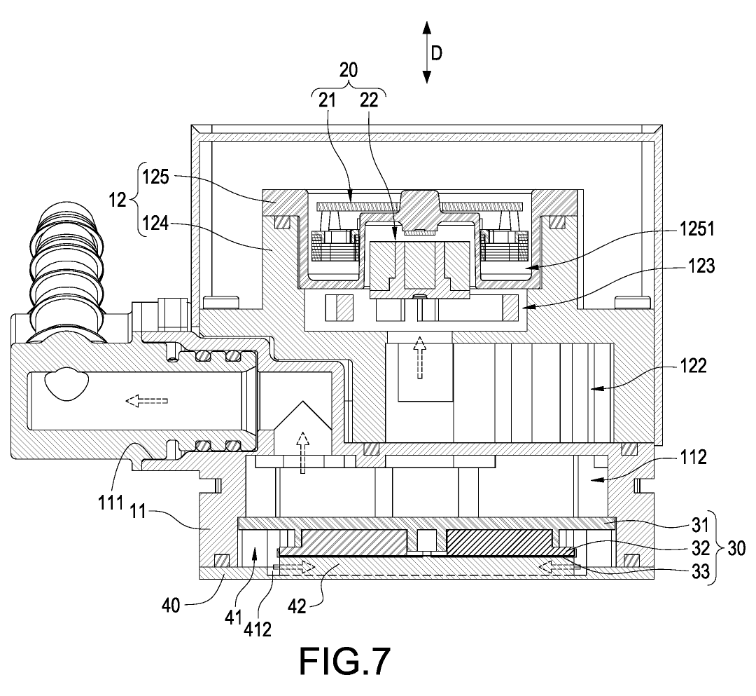

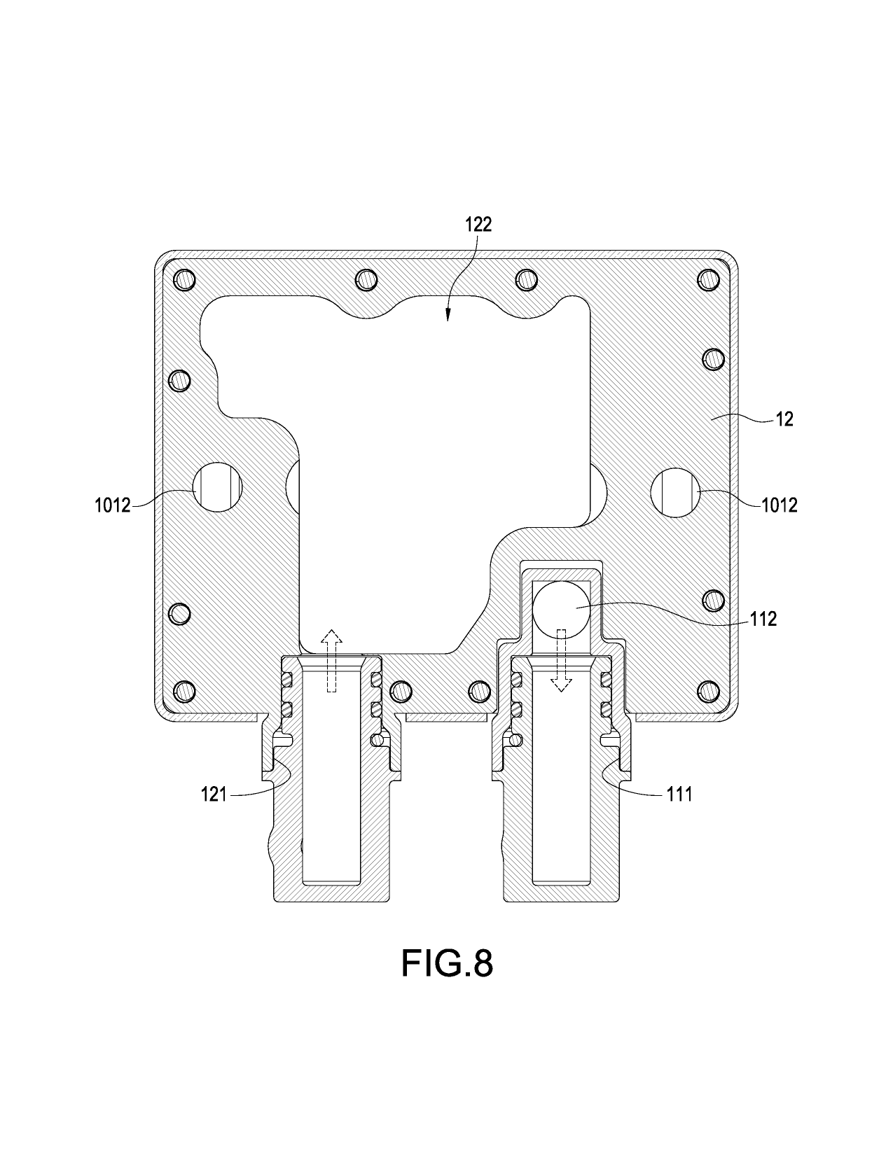

The base seat 10 includes a first seat 11 and a second seat 12. The first seat 11 is arranged on the base seat 40 along an up-down direction D. The second seat 12 is stacked on the first seat 11 along the up-down direction D. The first seat 11 has an outlet port 111 and a confluence cavity 112. The confluence cavity 112 is formed on a side of the first seat 11 away from the second seat 12. In detail, the confluence cavity 112 is formed on a bottom of the first seat 11. Please refer to FIG. 7 and FIG. 8, the outlet port 111 is defined on a top of the first seat 11 and communicated to the confluence cavity 112. The second seat 12 has an inlet port 121, a concentrated cavity 122, and a pair of accommodated grooves 123. The concentrated cavity 122 is formed on a side of the second seat 12 adjacent to the first seat 11. In detail, the concentrated cavity 122 is formed on a bottom of the second seat 12. Please refer to FIG. 6 and FIG. 8, the inlet port 121 is defined on a side of the second seat 12 and communicated to the concentrated cavity 122. In the embodiment, the inlet port 121 and the outlet port 122 are both located on the same side of the base seat 10 such that a pair of infusion tubes (not shown in figures) respectively connected to the inlet port 121 and the outlet port 122 may be easily organized, but the inlet port 121 and the outlet port 122 may also be located on the different sides of the base seat 10 in other embodiments. Each of the accommodated grooves 123 is arranged on a top of the second seat 12 in parallel and respectively communicated to the concentrated cavity 122. In other words, the inlet port 121 is communicated to each of the accommodated grooves 123 through the concentrated cavity 122. As shown in FIG. 5, the concentrated cavity 122 is completely located between the confluence cavity 112 and the pair of accommodated grooves 123. In detail, the confluence cavity 112, the concentrated cavity 122, and the pair of accommodated grooves 123 are sequentially configured to cascade along the up-down direction D. In addition, the base seat 10 has a pair of channels 101. Each of the channels 101 is configured to be corresponding to each of the accommodated grooves 123 and located on two different sides of the concentrated cavity 122. Please refer to FIG. 1, FIG. 2, FIG. 3, FIG. 4, and FIG. 5 again, each of the channels 101 in the embodiment is defined on the first seat 11 and the second seat 12 along the up-down direction D, the channels 101 are oppositely located on two sides of the base seat 10, but the present disclosure is not limited to this embodiment. For example, each of the channels 101 may also be configured to be tilted relative to the up-down direction D, or the channels 101 may also be located at a diagonal position of the base seat 10.

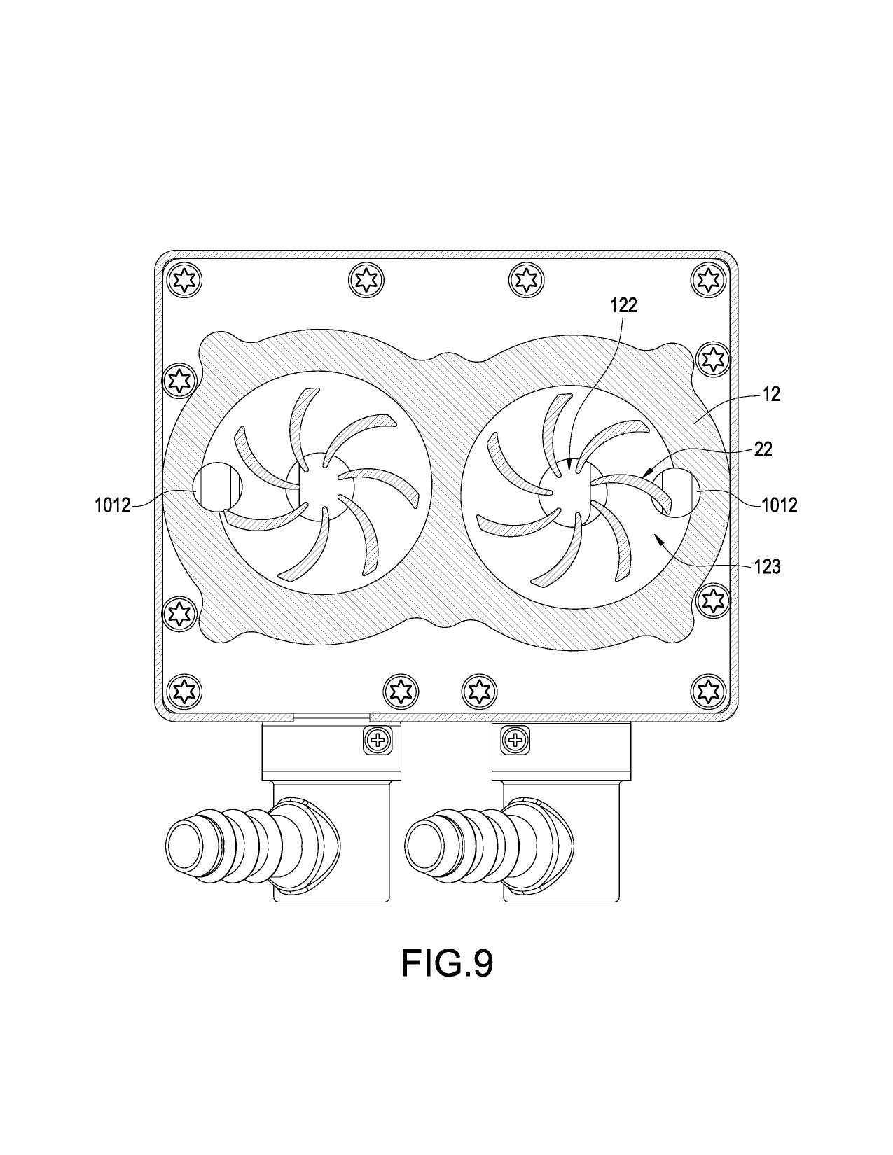

Please refer to FIG. 1, FIG. 2, FIG. 4, FIG. 5, and FIG. 9, each of the pumps 20 is configured to be corresponding to each of the accommodated grooves 123. In detail, the second seat 12 includes a main body 124 and a cover plate 125. The main body 124 has the inlet port 121, the concentrated cavity 122, and the accommodated grooves 123. The cover plate 125 has a pair of mounting grooves 1251. The cover plate 125 is arranged on a side of the main body 124 away from the first seat 11, and the cover plate 125 covers each of the accommodated grooves 123. Therefore, a bottom of the concentrated cavity 122 is covered by the first seat 11, a top of the concentrated cavity 122 is communicated to each of the accommodated grooves 123, and a top of each of the accommodated grooves 123 is covered by the cover plate 125. Each of the mounting grooves 1251 is configured to be corresponding to each of the accommodated grooves 123, and each of the mounting grooves 1251 is located on a side of the cover plate 125 away from the main body 124. In other words, the mounting grooves 1251 and the accommodated grooves 123 are respectively located on two opposite sides of the cover plate 125. Each of the pumps 20 includes a stator assembly 21 and a rotor assembly 22. Each of the rotor assemblies 22 is arranged in each of the accommodated grooves 123. Each of the stator assemblies 21 is arranged in each of the mounting grooves 1251. Since the specific structure and operation principle of the pumps 20 are well known in the art, they are not be described in detail.

Please refer to FIG. 1, FIG. 2, and FIG. 5, the separating assembly 30 covers a bottom of the confluence cavity 112. In detail, the separating assembly 30 is abutted against between the bottom seat 40 and the first seat 11. A heat exchange chamber 41 is formed between the separating assembly 30 and the bottom seat 40. Two ends of each of the channels 101 are respectively communicated to the heat exchange chamber 41 and the corresponding accommodated groove 123. The separating assembly 30 has a through slot group 301. The heat exchange chamber 41 is communicated to the confluence cavity 112 through the through slot group 301. Therefore, the coolant may converge in the concentrated cavity 122 of the second seat 12 after the coolant entering the inlet port 121, and then the coolant is absorbed from the concentrated cavity 122 to the accommodated grooves 123 by a suction force generated by the pumps 20 when they are running. The coolant sequentially enters the heat exchange chamber 41 through the channels 101, enters the confluence cavity 112 through the through slot group 301 of the separating assembly 30, and finally leaves from the outlet port 111. Therefore, the arrangement of the concentrated cavity 122 may increase the flow rate of the coolant in the duo-pump liquid cooling device of the present disclosure to improve heat dissipation efficiency and prevent the coolant from becoming insufficient due to evaporation or leakage after a period of use.

Details are provided as follows. The bottom seat 40 has a plurality of fins 42 arranged in parallel. Each of the fins 42 is arranged on a side of the bottom seat 40 facing the first seat 11 and the separating assembly 30, that is each of the fins 42 is arranged on a top of the bottom seat 40. A plurality of flow channels 43 parallel to each other is formed between each two of the fins 42. Two ends of each of the flow channels 43 are communicated to each of the channels 101. Each of the flow channels 43 is communicated to the confluence cavity 112 of the first seat 11 through the through slot group 301 of the separating assembly 30. In detail, the fins 42 separate the heat exchange chamber 41 to the flow channels 43, a pair of shunt areas 411, and a pair of inflow areas 412. Two ends of each of the flow channels 43 are respectively communicated to each of the inflow areas 412, that is the fins 42 and the flow channels 43 are all perpendicular between the inflow areas 412. Two ends of each of the inflow areas 412 are respectively communicated to each of shunt areas 411 such that the inflow areas 412 and the fins 42 are all located between the shunt areas 411. In other words, the inflow areas 412 and the shunt areas 411 are arranged on an outer periphery of the fins 42 and the flow channels 43 to surround them. An end of each of the channels 101 communicated to the heat exchange chamber 41 is communicated to the corresponding shunt area 411. In the embodiment, a location of each of the channels 101 communicated to the corresponding shunt area 411 is located at a center of the shunt area 411, but the present disclosure is not limited to this embodiment, as long as the location of each of the channels 101 communicated to the corresponding shunt area 411 is located between two ends of the shunt area 411. Therefore, when the coolant flows to the heat exchange chamber 41 through the channels 101, the coolant first enters to the center of the shunt area 411 to divide to two sides to each of the inflow areas 412, the coolant then flows from each of the inflow areas412 into each of the flow channels 43 between each of the fins 42, and the coolant finally leaves the heat exchange chamber 41 from the through slot group 301 of the separating assembly 30.

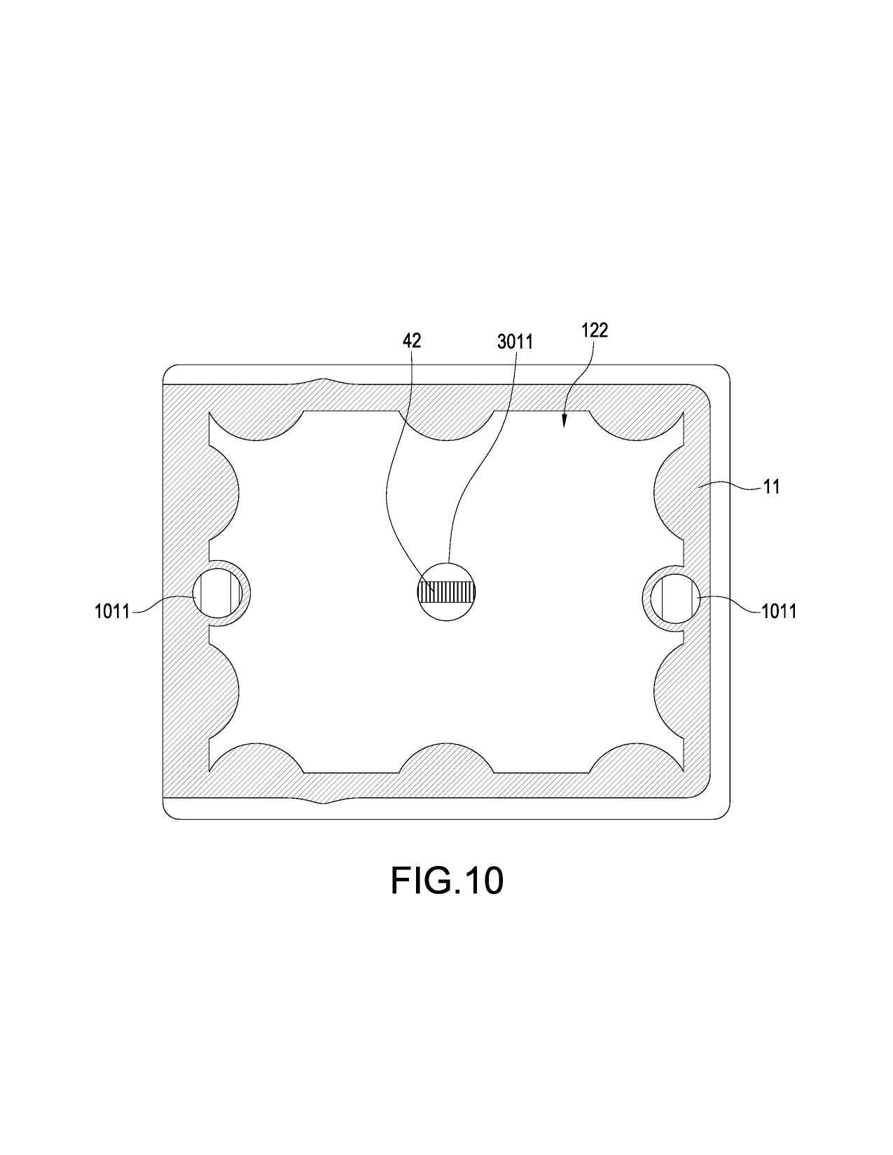

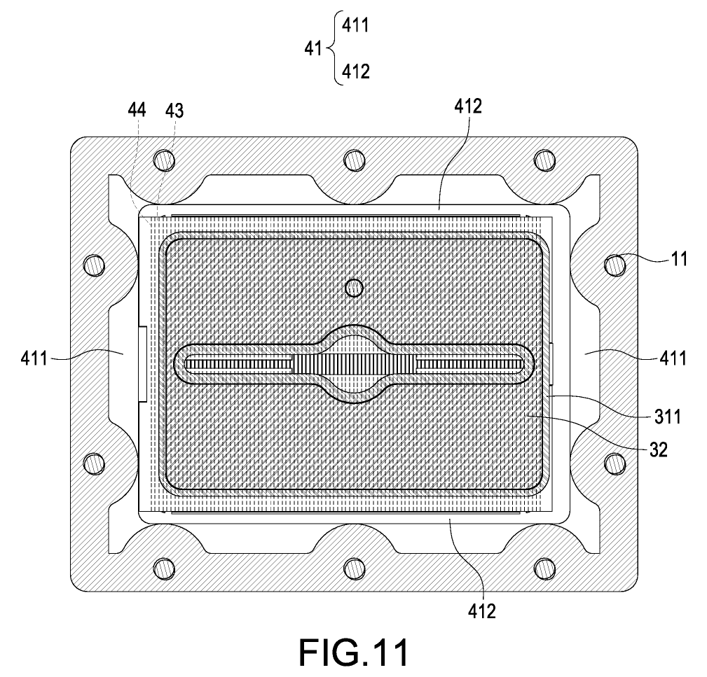

Please refer to FIG. 1, FIG. 2, FIG. 5, FIG. 10, and FIG. 11, the separating assembly 30 includes a separating plate 31, a diversion plate 32, and an abutting sheet 33. In the embodiment, the separating plate 31 and the abutting sheet 33 are both made of metal, the diversion plate 32 is made of silicone or rubber, but the present disclosure is not limited to this embodiment. The separating plate 31 is abutted against and arranged between the first seat 11 and the diversion plate 32. The abutting sheet 33 is abutted against and arranged between the diversion plate 32 and each of the fins 42 of the bottom seat 40. In other words, the abutting sheet 33, the diversion plate 32, and the separating plate 31 are sequentially stacked on a top of each of the fins 42 of the bottom seat 40 along the up-down direction D.

The separating plate 31 has a surrounding wall 311. The diversion plate 32 has a fixing groove 321. In detail, the surrounding wall 311 is extended from a side of the separating plate 31 facing the diversion plate 32 to be rectangular shaped. The fixing groove 321 is concave from a top periphery of the diversion plate 32 to be a hollow-rectangular groove. The surrounding wall 311 of the separating plate 31 is fixed to the fixing groove 321 of the diversion plate 32, so as to limit a top of the diversion plate 32 in the surrounding wall 311 of a bottom of the separating plate 31.

In addition, the abutting sheet 33 has a pair of limiting baffles 331 located on two opposite sides thereof. The diversion plate 32 has a pair of positioning baffles 322 located on two opposite sides thereof. Each of the limiting baffles 331 of the abutting sheet 33 is perpendicularly extended toward the diversion plate 32 along the up-down direction D such that the diversion plate 32 is limited between each two of the limiting baffles331. Each of the positioning baffles 322 of the diversion plate 32 is perpendicularly extended toward the abutting sheet 33 along the up-down direction D such that the abutting sheet 33 is limited between each two of the positioning baffles 322 and located between each two of the limiting baffles 331. In other words, the limiting baffles 331 of the abutting sheet 33 limit two opposite sides of the diversion plate 32, and the positioning baffles 322 of the diversion plate 32 are located on the other two sides of the diversion plate 32.

Therefore, the separating plate 31 and the diversion plate 32 may be positioned relative to each other without relative displacement, and the diversion plate 32 and the abutting sheet 33 may also be positioned relative to each other without relative displacement. In addition, since the diversion plate 32 made of silicone or rubber is clamped between the separating plate 31 and the abutting sheet 33 that are made of metal, the diversion plate 32 may effectively prevent from being deformed or displaced by a strong upward impact of the coolant along the up-down direction D, so as to ensure the coolant may flow stably when passing through the separating assembly 30.

Details are provided as follows. Please refer to FIG. 1, FIG. 2, FIG. 5, FIG. 10, and FIG. 11 again, the through slot group 301 includes a through hole 3011, a first through slot 3012, a second through slot 3013, and a third through slot 3014. The through hole 3011 and the first through slot 3012 are defined on the separating plate 31. In detail, the through hole 3011 is a circle hole and passes through the separating plate 31 along the up-down direction D, and the first through slot 3012 is defined on a bottom of the separating plate 31 and communicated to the through hole 3011. The separating plate 31 has an embedded block 312 extended from a side of the separating plate 31 facing the diversion plate 32. The second through slot 3013 passes through the diversion plate 32 along the up-down direction D, and a shape of the second through slot 3013 is corresponding to a shape of the embedded block 312. The embedded block 312 of the separating plate 31 is fixed to the second through slot 3013 of the diversion plate 32 to further position the separating plate 31 and the diversion plate 32. The first through slot 3012 is located in the embedded block 312 and communicated to the second through slot 3013. In the embodiment, a center of the first through slot 3012 is a circle hole, two opposite sides of the first through slot 3012 respectively extend a strip hole, and a diameter of the circle hole at the center of the first through slot 3012 is larger than a width of each of the strip holes at two opposite sides of the first through slot 3012. However, the present disclosure is not limited to this embodiment. The third through slot 3014 passes through the abutting sheet 33 along the up-down direction D. The third through slot 3014 is communicated to the first through slot 3012 and the second through slot 3013, so as to be communicated to the through hole 3011. In the embodiment, the third through slot 3014 is long strip shaped to form two narrow sections and a wide section. A location of the wide section is approximately corresponding to a location of the circle hole at the center of the first through slot 3012. The narrow sections are communicated to two opposite sides of the wide section and approximately corresponding to the strip holes of the first through slot 3012. However, the present disclosure is not limited to this embodiment.

It is worth noting that the through slot group 301 of the separating assembly 30 is substantially perpendicular to each of the fins 42 and each of the flow channels 43, and the through slot group 301 is approximately located at a center of each of the fins 42 and each of the flow channels 43. In detail, as FIG. 1 and FIG. 2 for example. Each of the fins 42 and each of the flow channels 43 is parallel to a front-rear direction (a defined direction of the inlet port 121 and the outlet port 111), and the first through slot 3012 and the third through slot 3014 of the through slot group 301 are parallel to a left-right direction of the base seat 10 and the bottom seat 40 such that the first through slot 3012 and the third through slot 3014 are both perpendicular to each of the fins 42 and each of the flow channels 43. Therefore, the coolant will flow to the center of each of the fins 42 and each of the flow channels 43 when the coolant enters each of the flow channels 43 from each of the inflow areas 412, and then the coolant sequentially enters the third through slot 3014, the second through slot 3013, the first through slot 3012, and the through hole 3011 along the up-down direction D to converge in the confluence cavity 112 of the first seat 11 through the separating assembly 30. In addition, when the coolant passes through the third through slot 3014 and the first through slot 3012, the coolant will gradually converge toward the wide section and the circle hole to flow out of the through hole 3011 of the separating assembly 30because of affecting by the narrow sections and the strip holes.

Please refer to FIG. 1, FIG. 2, FIG. 3, FIG. 4, and FIG. 5 again, each of the channels 101 includes a first channel section 1011 and a second channel section 1012 communicated to each other. Each of the first channel sections 1011 is defined on the first seat and communicated to the heat exchange chamber 41 and the corresponding second channel section 1012. Each of the second channel sections 1012 is defined on the second seat 12 and communicated to the corresponding accommodated groove 123 and the corresponding first channel section 1011. In the embodiment, the first channel section 1011 and the second channel section 1012 in each of the channels 101 have the same inner diameter and are configured to be coaxial, but the first channel section 1011 and the second channel section 1012 in each of the channels 101 in other embodiments may also have the different inner diameters and are configured to not be coaxial.

In the duo-pump liquid cooling device of the present disclosure, the second seat 12 forms the concentrated cavity 122, and the pumps 20 are arranged in the accommodated grooves 123 in parallel. Therefore, the coolant may converge in the concentrated cavity 122 after entering from the inlet port 121, and then the coolant sequentially enters the accommodated grooves 123, the channels 101, and the heat exchange chamber 41 by a suction force generated by the pumps 20 when they are running. The duo-pump liquid cooling device of the present disclosure is therefore increasing the flow rate of the coolant therein to improve heat dissipation efficiency and preventing the coolant from becoming insufficient due to evaporation or leakage after a period of use.

It shall be understood that the present disclosure may have other types of embodiments, and a person with ordinary skills in the art of the technical field of the present disclosure may make various changes and modifications corresponding to the present disclosure without deviating the principle and substance of the present disclosure; however, such corresponding changes and modification shall be considered to be within the claimed scope of the present disclosure.

What is claimed is:

1. A duo-pump liquid cooling device, comprising:
a base seat, comprising a first seat, a second seat, and a pair of channels, the second seat arranged on the first seat, the first seat comprising an outlet port and a confluence cavity communicated to the outlet port, the second seat comprising an inlet port, a concentrated cavity, and a pair of accommodated grooves, the inlet port communicated to the concentrated cavity, each of the accommodated grooves arranged in parallel and respectively communicated to the concentrated cavity, the concentrated cavity completely located between the confluence cavity and the pair of accommodated grooves, each of the channels corresponding to each of the accommodated grooves and located on two sides of the concentrated cavity;
a pair of pumps, corresponding to each of the accommodated grooves;
a separating assembly, covering the confluence cavity and comprising a through slot group; and
a bottom seat, wherein the first seat is arranged on the bottom seat to form a heat exchange chamber between the separating assembly and the bottom seat, two ends of each of the channels are respectively communicated to the heat exchange chamber and the corresponding accommodated groove, the heat exchange chamber is communicated to the confluence cavity through the through slot group.

2. The duo-pump liquid cooling device according to claim 1, wherein the bottom seat comprising a plurality of fins arranged in parallel, a plurality of flow channels is formed between each two of the fins, two ends of each of the flow channels are communicated to each of the channels, each of the flow channels is communicated to the confluence cavity through the through slot group.

3. The duo-pump liquid cooling device according to claim 2, wherein each of the fins separates the heat exchange chamber to each of the flow channels, a pair of shunt areas, and a pair of inflow areas, two ends of each of the flow channels are respectively communicated to each of the inflow areas, two ends of each of the inflow areas are respectively communicated to each of shunt areas, each of the inflow areas and each of the fins are located between each two of the shunt areas, an end of each of the channels communicated to the heat exchange chamber is communicated to the corresponding shunt area.

4. The duo-pump liquid cooling device according to claim 3, wherein a location of each of the channels communicated to the corresponding shunt area is located at a center of the shunt area.

5. The duo-pump liquid cooling device according to claim 1, wherein the separating assembly comprises a separating plate and a diversion plate, the separating plate is arranged between the first seat and the diversion plate.

6. The duo-pump liquid cooling device according to claim 5, wherein the separating assembly further comprises an abutting sheet, the abutting sheet is arranged between the diversion plate and the bottom seat, the abutting sheet comprises a pair of limiting baffles, the diversion plate comprises a pair of positioning baffles, the diversion plate is limited between each two of the limiting baffles, the abutting sheet is limited between each two of the positioning baffles and located between each two of the limiting baffles.

7. The duo-pump liquid cooling device according to claim 1, wherein the second seat comprises a main body and a cover plate, the main body comprises the inlet port, the concentrated cavity, and the accommodated grooves, the cover plate comprises a pair of mounting grooves, is arranged on the main body, and covers each of the accommodated grooves, each of the mounting grooves is configured to be corresponding to each of the accommodated grooves.

8. The duo-pump liquid cooling device according to claim 7, wherein each of the pumps comprises a stator assembly and a rotor assembly, each of the rotor assemblies is arranged in each of the accommodated grooves, each of the stator assemblies is arranged in each of the mounting grooves.

9. The duo-pump liquid cooling device according to claim 7, wherein each of the channels comprises a first channel section and a second channel section communicated to each other, each of the first channel sections is defined on the first seat and communicated to the heat exchange chamber and the corresponding second channel section, each of the second channel sections is defined on the second seat and communicated to the corresponding accommodated groove and the corresponding first channel section.

10. The duo-pump liquid cooling device according to claim 1, wherein the inlet port and the outlet port are located on same side of the base seat.
